(19) United States
(12) Patent Application Publication
(10) Pub. No.: US 2024/0153922 A1
(43) Pub. Date: May 9, 2024

(54) DISPLAY DEVICE

(71) Applicant: KYOCERA Corporation, Kyoto-shi, Kyoto (JP)

(72) Inventors: Masaya TAMAKI, Yokohama-shi, Kanagawa (JP); Shinichiro MORIKAWA, Kyotanabe-shi, Kyoto (JP); Takeomi MORITA, Ryuo-cho, Shiga (JP); Megumi OOISHI, Ritto-shi, Shiga (JP)

(21) Appl. No.: 18/280,910

(22) PCT Filed: Mar. 2, 2022
(86) PCT No.: PCT/JP2022/008984

§ 371 Date: Sep. 7, 2023

(30) Foreign Application Priority Data
Mar. 8, 2021 (JP) 2021-036684

(51) Int. Cl. H01L 25/075; H01L 33/58

(52) U.S. Cl. CPC H01L 25/0753; H01L 33/58

(57) ABSTRACT

A structure includes a cavity structure including a display surface and a cavity in the display surface, and a light emitter in the cavity. The display surface includes a first area that displays information with light emitted from the light emitter in the cavity and a second area adjacent to the first area. A ratio of a first brightness of the first area in a non-display state to a second brightness of the second area is in a predetermined range including 1.

### TECHNICAL FIELD

The present disclosure relates to a display device with a display surface including a display portion including a light emitter and a non-display portion other than the display portion.

### BACKGROUND OF INVENTION

A known display device is described in, for example, Patent Literature 1. Another known display device is described in, for example, Patent Literature 2.

### CITATION LIST

### Patent Literature

Patent Literature 1: Japanese Unexamined Patent Application Publication No. 2005-62441
Patent Literature 2: Japanese Unexamined Patent Application Publication No. 2007-220465

### SUMMARY

In an aspect of the present disclosure, a display device includes a cavity structure including a display surface and a cavity in the display surface, and a light emitter in the cavity. The display surface includes a first area that displays information with light emitted from the light emitter in the cavity and a second area adjacent to the first area. A ratio of a first brightness of the first area in a non-display state to a second brightness of the second area is in a predetermined range including 1.

### BRIEF DESCRIPTION OF THE DRAWINGS

The objects, features, and advantages of the present invention will become more apparent from the following detailed description and the drawings.

FIG. 1A is a schematic cross-sectional view of a display device 1 according to an embodiment of the present disclosure.

FIG. 1B is a partial plan view of the display device 1 in FIG. 1A as viewed from above.

FIG. 2 is a cross-sectional view of a cavity structure 4 in a variation integral with the display device 1 illustrated in FIGS. 1A and 1B.

FIG. 3 is an enlarged partial cross-sectional view of part III in FIGS. 1A and 2.

FIG. 4A is a graph showing the brightness of a first area A1 and a second area A2.

FIG. 4B is an enlarged partial plan view of a display surface 2.

FIG. 5A is a graph showing the detailed brightness of portions P1, P2, and P3 in a boundary part P.

FIG. 5B is an enlarged partial plan view of the boundary part P.

FIG. 6 is a schematic exploded partial cross-sectional view of the display device 1.

FIG. 7 is a cross-sectional view of the cavity structure 4 mounted on a first substrate 12.

FIG. 8 is an enlarged partial plan view of the display surface 2.

FIG. 9 is an enlarged partial plan view of part IX in FIG. 8.

FIG. 10 is an enlarged partial plan view of a display device 1A according to another embodiment of the present disclosure, illustrating a boundary part P on a display surface 2.

FIG. 11 is an enlarged partial plan view of a display device 1B according to another embodiment of the present disclosure, illustrating a boundary part P on a display surface 2.

FIG. 12 is an enlarged partial plan view of a display device 1C according to another embodiment of the present disclosure, illustrating a boundary part P on a display surface 2.

FIG. 13 is an enlarged partial plan view of a display device 1D according to another embodiment of the present disclosure, illustrating a boundary part P on a display surface 2.

FIG. 14 is an enlarged partial plan view of a display device 1E according to another embodiment of the present disclosure, illustrating a boundary part P on a display surface 2.

FIG. 15A is a diagram illustrating a process of printing sublimation ink in reverse on transfer paper.

FIG. 15B is a diagram illustrating a process of pressing a fabric and the transfer paper together with heat.

FIG. 15C is a diagram illustrating a process of the sublimation ink evaporating and fixing on the fabric.

FIG. 16A is a cross-sectional view of the first substrate 12 with transfer paper 33 on the substrate.

FIG. 16B is a cross-sectional view of the first substrate 12 after the transfer paper 33 is peeled off.

FIG. 16C is a cross-sectional view of the first substrate 12 with ink 30 transferred.

FIG. 17A is a cross-sectional view of a transferred printed layer 17 having a thickness T greater than half a width W of an opening.

FIG. 17B is a cross-sectional view of the transferred printed layer 17 having the thickness T greater than half the width W of the opening.

FIG. 17C is a cross-sectional view of the transferred printed layer 17 having the thickness T greater than half the width W of the opening.

### DESCRIPTION OF EMBODIMENTS

The objects, features, and advantages of the present invention will become more apparent from the following detailed description and the drawings.

The structure that forms the basis of a display device according to one or more embodiments of the present disclosure will now be described. Patent Literature 1 describes a known display device with the structure below. When no light emitter is on, the display device including a surface plate with a sheet displays the state of a display surface of the sheet. When the sheet is transparent, the display device displays an image illustrated on a side surface of an area light source. When light emitters are on, light from the light emitters is emitted through the sheet to the display surface to allow text, graphics, or symbols corresponding to the light emitters to appear.

A known display device in Patent Literature 2 splits light from a light source into light directed outside through a light emitting surface of a lens and leaking light not used for lighting. The leaking light is guided through a transparent or translucent lens holder and a decorative plate before reaching outside. A lighting tool with this structure glows entirely, rather than partly from the light emitting surface of the lens, thus serving as an interior decoration while functioning as a light.

With the known techniques described in Patent Literatures 1 and 2, a first area displays predetermined display information with light from the light emitters, and a second area other than the first area includes no light emitter. When the light emitters are not on and emit no light, the first area is unintendedly viewed as an area different from the second area. This often causes discomfort for a viewer. In other words, when the light emitters are not on, the first area has, for example, a brightness different from the brightness of the second area other than the first area. This causes loss of continuity between the first area and the second area, thus increasing the likelihood of causing discomfort for the viewer. Thus, display devices with high image quality that reduce such discomfort for the viewer when no light is emitted have been awaited.

A light-emitting device according to one or more embodiments of the present disclosure will now be described with reference to the accompanying drawings.

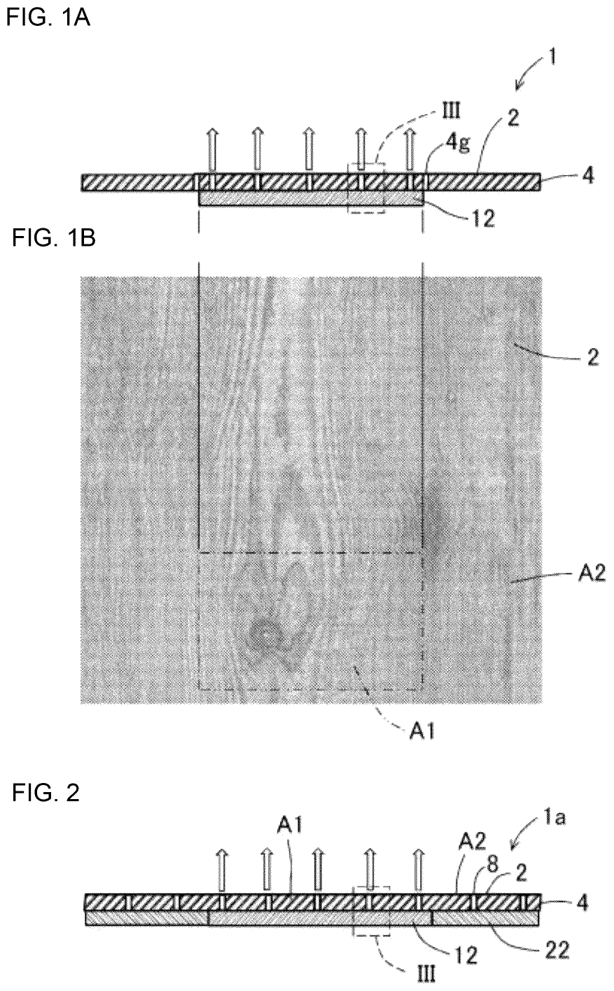

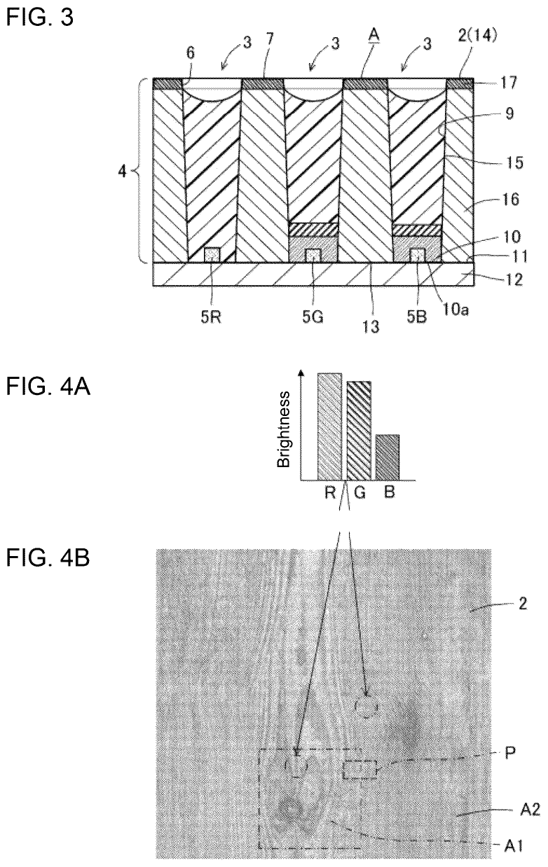

FIG. 1A is a schematic cross-sectional view of a display device 1 according to an embodiment of the present disclosure. FIG. 1B is a partial plan view of the display device 1 in FIG. 1A as viewed from above. In FIGS. 1A and 1B, a first area A1 and a second area A2 are separate with a separator 4g between the first area A1 and the second area A2. FIG. 2 is a cross-sectional view of a cavity structure 4 in a variation integral with the display device 1 illustrated in FIGS. 1A and 1B. In FIG. 2, the first area A1 and the second area A2 are integral with each other. FIG. 3 is an enlarged partial cross-sectional view of part III in FIGS. 1A and 2. For ease of explanation, dimensions such as thicknesses differ from actual products and are schematically illustrated with exaggeration in FIGS. 1A to 3.

In the present embodiment, the display device 1 includes the cavity structure 4 including a display surface 2 and multiple cavities 3 in the display surface 2, and multiple light emitters 5R, 5G, and 5B accommodated in the respective cavities 3. As illustrated in FIG. 3, the light emitters 5R, 5G, and 5B may be covered with, for example, a wavelength conversion layer including a wavelength conversion member such as a fluorescent substance, or a color filter layer. The light emitters 5R, 5G, and 5B are hereafter collectively referred to as light emitters 5.

The cavity structure 4 includes at least one cavity 3. For example, the cavity structure 4 including one cavity 3 may include one light emitter 5 accommodated in the cavity 3. The display device 1 with this structure may serve as, for example, an alarm device. In some embodiments, the cavity structure 4 including one cavity 3 may include multiple light emitters 5 with different emission colors in the cavity 3. This structure can control the color of light emitted from the cavity 3 outside. The display device 1 may thus serve as, for example, a signal device. The cavity structure 4 may include multiple cavities 3. The display device 1 with this structure may serve as, for example, an image display device.

The display device 1 includes the display surface 2 including the first area A1 for displaying information with light emitted from the light emitters 5 in the cavities 3, and the second area A2 adjacent to the first area A1. The ratio of a first brightness of the first area A1 in a non-display state to a second brightness of the second area A2 is in a predetermined range including 1. More specifically, the first brightness of the first area A1 in the non-display state is substantially equal to the second brightness of the second area A2. This structure produces the advantageous effects described below. The first area and the second area are more likely to be viewed as continuous areas by a viewer when the light emitters are off. This reduces the likelihood that the first area, which emits light for display, is unintendedly viewed intermittently as an area different from the second area when no light is emitted. The display device can thus have higher image quality while emitting no light.

The first area A1 may display information of the same type, such as image or text information, as information displayed by a common display device such as a liquid crystal display (LCD) device. Each cavity has the shape of a recess and is also referred to a recess, but is referred to as a cavity below.

Each light emitter 5 may be a micro-light-emitting diode (μLED). The light emitter 5R includes a red μLED for emitting red light. The light emitter 5G includes a green μLED for emitting green light. The light emitter 5B includes a blue μLED for emitting blue light. In place of the μLED above, each light emitter 5 may be a self-luminous light emitter such as an organic electroluminescent (OEL) element or a semiconductor laser diode (LD).

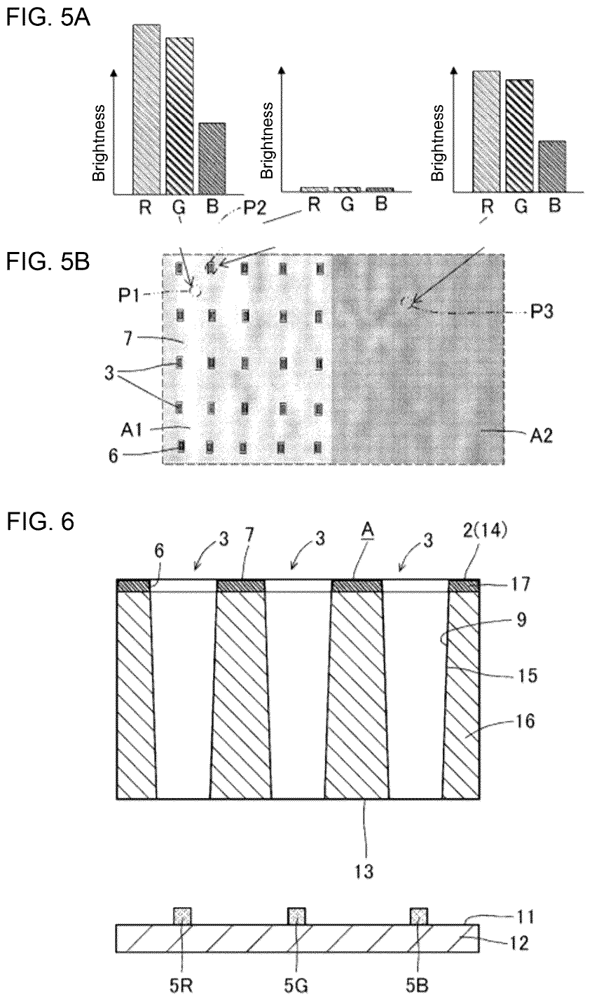

FIGS. 4A and 4B are diagrams describing the brightness of the display surface 2 of the display device 1. FIG. 4A is a graph showing the brightness of the first area A1 and the second area A2. FIG. 4B is a partial plan view of the display surface 2. As in FIG. 4A, in the display device 1 according to one or more embodiments of the present disclosure, the first area A1 in the non-display state has substantially the same brightness as the second area A2. FIGS. 5A and 5B are diagrams describing the detailed brightness of portions in a boundary part P in FIG. 4B. FIG. 5A is a graph showing the brightness of portions P1, P2, and P3 in the boundary part P. FIG. 5B is an enlarged partial plan view of the boundary part P. The graphs of the brightness show the relative intensity of light separated into red (R), blue (B), and green (G) light. Red light has a wavelength in a range of about 640 to about 770 nm. Green light has a wavelength in a range of about 490 to about 555 nm. Blue light has a wavelength in a range of about 430 to about 490 nm. A range of values referred to herein as one value to another value intends to mean the two values being inclusive.

More specifically, the display device 1 satisfies

V1=V11×S11/S1+V12×S12/S1,

where S1 is the area size of the first area A1, V11 is the brightness (defined by the Munsell color system) in the non-display state of openings 6 of the cavities 3 in the first area A1, S11 is a total area size of the openings 6 in the first area A1, V12 is the brightness of a portion 7 of the first area A1 other than the openings 6, S12 is the area size of the portion 7 of the first area A1 other than the openings 6, V1 is the first brightness, V2 is the second brightness, and S1=S11+S12. The predetermined range may be 0.8≤V1/V2≤1.2. Without the ratio V1/V2 being in this range, the first area A1 and the second area A2 are more likely to be viewed by a viewer as intermittent areas when the light emitters 5 are not on. The first brightness V1 is the average (merged value) of the brightness values V11 and V12 at the respective ratios of the area sizes S11 to S1 and S12 to S1.

The total referred to above is a total of a single object (e.g., an opening 6) to be measured, or is a total of multiple objects to be measured.

The brightness V11 of the openings 6 in the non-display state may be lower than the brightness V12 of the portion of the first area A1 other than the openings 6. The openings 6 are then less visible in the non-display state. The difference between V12 and V11 may fall within 1 to 5. When the difference between V11 and V12 is greater than 5 which is too large, the openings 6 may be more visible.

Hereafter, the brightness of the color of an object may be denoted as V1 after “value” in the Munsell color system, the hue may be denoted as H1 after “hue circle” in the system, and the chroma may be denoted as C1 after “chroma” in the system.

The brightness V is determined with reference to neutral colors such as white, black, and gray. The brightest white is assigned with 10. The darkest black is assigned with 0. Grays are assigned with values ranging from 1 to 9. The actual color samples are unlikely to include a sample that reflects light completely (value 10) and a sample that absorbs light completely (value 0). Thus, white is often expressed using 9.5, and black is often expressed using 1. In the hue circle H, the colors are divided into red (R), yellow (Y), green (G), blue (B), and purple (P) hues, and also five intermediate YR, GY, BG, PB, and RP hues. Each hue is further divided into 10 hues. The hue circle H thus has 100 hues. The 10 basic colors are expressed using 5 suffixed to the color name. The 10 basic colors are each further divided into 10 colors, which are expressed using 1 to 4 and 6 to 10 suffixed to the color names. For example, yellow is expressed using 5Y, and blue green is expressed using SBG. The chroma C indicates the vividness of a color. Colorless achromaticity is expressed using 0. The value increases as the degree of the vividness of a color increases. The maximum value of chroma varies depending on the brightness V and the hue H. The maximum value of chroma is, for example, 14 for 5R at the highest and is 10 for SBG.

In the display device 1, the ratio of a first hue of the first area A1 in the non-display state to a second hue of the second area A2 may be in a predetermined range including 1. More specifically,

H1=H11×S11/S1+H12×S12/S1,

where H11 is the hue (defined by the Munsell color system) of the openings 6 of the cavities 3 in the first area A1 in the non-display state, H12 is the hue of the portion 7 of the first area A1 other than the openings 6, H1 is the first hue, H2 is the second hue, and S1=S11+512, where S11 and S12 are as described above. The predetermined range may be 0.8≤H1/H2≤1.2. Without the ratio H1/H2 being in this range, the first area A1 and the second area A2 are more likely to be viewed by a viewer as intermittent areas when the light emitters 5 are not on. The first hue H1 is the average (merged value) of the values H11 and H12 at the respective ratios of the area sizes S11 to S1 and S12 to S1.

In the display device 1, the ratio of a first chroma of the first area A1 in the non-display state to a second chroma of the second area A2 may be in a predetermined range including 1. More specifically,

C1=C11×S11/S1+C12×S12/S1,

where C11 is the chroma (defined by the Munsell color system) of the openings of the cavities in the first area in the non-display state, C12 is the hue of the portion of the first area other than the openings, C1 is the first chroma, and C2 is the second chroma, and S1=S11+S12, where S11 and S12 are as described above. The predetermined range may be 0.8≤C1/C2≤1.2. Without the ratio C1/C2 being in this range, the first area A1 and the second area A2 are more likely to be viewed by a viewer as intermittent areas when the light emitters 5 are not on. The first chroma C1 is the average (merged value) of the values C11 and C12 at the respective ratios of the area sizes S11 to S1 and S12 to S1.

When the portion 7 of the first area A1 other than the openings 6 has the brightness V12 not uniform across the portion, the brightness V12 may be determined as the average written by

V12={ΔV12(1)+ΔV12(2)+ . . . +ΔV12(n)}/n,

where ΔV12(n) is the brightness per unit area size being a square portion having an area size of, for example, 1 cm 2 or 1 mm², and n is an integer greater than or equal to 2. The second brightness V2 of the second area A2 may be determined as the average in the same or similar manner. The hue H12 of the portion 7 of the first area A1 other than the openings 6 and the second hue H2 of the second area A2 may each be determined as the average in the same or similar manner. The chroma C12 of the portion 7 of the first area A1 other than the openings 6 and the second chroma C2 of the second area A2 may each be determined as the average in the same or similar manner.

The second area A2 may include optical adjusters corresponding to the openings 6 of the cavities 3. The optical adjusters adjust at least the second brightness V2. More specifically, multiple open display portions 8 (illustrated in FIG. 2) as the optical adjusters may be arranged in a matrix in the second area A2 in the display surface 2 with the openings 6 of the multiple cavities 3 arranged in a matrix in the first area A1 of the display surface 2. The multiple open display portions 8 are arranged two-dimensionally at the same intervals as the multiple openings 6. In other words, the open display portions 8 in the second area A2 are arranged in the same pattern as the openings 6 in the first area A1. When the open display portions 8 are hollow and each include a through-hole, a backlight device 22 (illustrated in FIG. 2) may be located on the back surface of the second area A2. The luminance of the backlight device 22 can be adjusted to adjust, for example, the luminance of light emitted from the open display portions 8 toward the display surface 2. In some embodiments, the open display portions 8 may be in the first area A1. Some of the multiple openings 6 may be the open display portions 8.

The structure described above may satisfy 0.9≤V11/V21≤1.1, where V11 is the brightness (defined by the Munsell color system) of the openings 6 of the cavities 3 in the non-display state, and V21 is the brightness of the optical adjusters. In this case, the values V11 and V21 may be approximated to increase the likelihood that the first area A1 and the second area A2 are viewed by a viewer as continuous areas when the light emitters 5 are not on.

As illustrated in FIG. 3, the cavity structure 4 includes a first substrate 12 with a first surface 11 including bottom surfaces 10a of the multiple cavities 3. The cavity structure 4 also includes a second substrate 16 located on the first surface 11. The second substrate 16 includes a second surface 13 facing the first surface 11, and a third surface 14 being the display surface 2 opposite to the second surface 13. The second substrate 16 includes multiple through-holes 9 extending from portions of the second surface 13 corresponding to the bottom surfaces 10a to the third surface 14 and defining the inner peripheral surfaces 15 of the corresponding multiple cavities 3. The light emitters 5 are located in the middle of the bottom surfaces 10a exposed through the through-holes 9.

The first substrate 12 is made of, for example, a glass material, a ceramic material, a resin material, a metal material, or a semiconductor material. Examples of the glass material used for the first substrate 12 include borosilicate glass, crystallized glass, quartz, and soda glass. Examples of the ceramic material used for the first substrate 12 include alumina (Al₂O₃), aluminum nitride (AlN), silicon nitride (Si₃N₄), zirconia (ZrO₂), and silicon carbide (SiC). Examples of the resin material used for the first substrate 12 include an epoxy resin, a polyimide resin, and a polyamide resin. Examples of the metal material used for the first substrate 12 include aluminum (Al), titanium (Ti), beryllium (Be), magnesium (Mg) (specifically, high-purity magnesium with a Mg content of 99.95% or higher), zinc (Zn), tin (Sn), copper (Cu), iron (Fe), chromium (Cr), nickel (Ni), and silver (Ag). The metal material used for the first substrate 12 may be an alloy material. Examples of the alloy material used for the first substrate 12 include an iron alloy mainly containing iron (a Fe—Ni alloy, a Fe—Ni—Co (cobalt) alloy, a Fe—Cr alloy, or a Fe—Cr—Ni alloy), duralumin, which is an aluminum alloy mainly containing aluminum (an Al—Cu alloy, an Al—Cu—Mg alloy, or an Al—Zn—Mg—Cu alloy), a magnesium alloy mainly containing magnesium (a Mg—Al alloy, a Mg—Zn alloy, or a Mg—Al—Zn alloy), titanium boride, and a Cu—Zn alloy. Examples of the semiconductor material used for the first substrate 12 include silicon (Si), germanium (Ge), and gallium arsenide (GaAs). The first substrate 12 may include a single layer of, for example, the glass material, the ceramic material, the resin material, the metal material, or the semiconductor material described above, or may be a stack of multiple layers of any of these materials. For the first substrate 12 being a stack of multiple layers, the layers may be made of the same or different materials.

The second substrate 16 is made of, for example, a glass material, a ceramic material, a resin material, a metal material, or a semiconductor material. Examples of the glass material used for the second substrate 16 include borosilicate glass, crystallized glass, quartz, and soda glass. Examples of the ceramic material used for the second substrate 16 include alumina, aluminum nitride, silicon nitride, zirconia, and silicon carbide. Examples of the resin material used for the second substrate 16 include an epoxy resin, a polyimide resin, and a polyamide resin. Examples of the metal material used for the second substrate 16 include aluminum, titanium, beryllium, magnesium (specifically, high-purity magnesium with a Mg content of 99.95% or higher), zinc, tin, copper, iron, chromium, nickel, and silver. The metal material used for the second substrate 16 may be an alloy material. Examples of the alloy material used for the second substrate 16 include an iron alloy mainly containing iron (a Fe—Ni alloy, a Fe—Ni—Co alloy, a Fe—Cr alloy, or a Fe—Cr—Ni alloy), duralumin, which is an aluminum alloy mainly containing aluminum (an Al—Cu alloy, an Al—Cu—Mg alloy, or an Al—Zn—Mg—Cu alloy), a magnesium alloy mainly containing magnesium (a Mg—Al alloy, a Mg—Zn alloy, or a Mg—Al—Zn alloy), titanium boride, and a Cu—Zn alloy. Examples of the semiconductor material used for the second substrate 16 include silicon, germanium, and gallium arsenide.

When the light emitters 5 are not on, the portion including the cavities 3 (openings 6) is darker (or brighter) than the portion 7 other than the openings 6. Thus, a viewer viewing the entire display surface 2 from a distant position views the average brightness of the first area A1 being different from the brightness of the second area A2. The viewer may feel discomfort from the difference in brightness between the first area A1 and the second area A2.

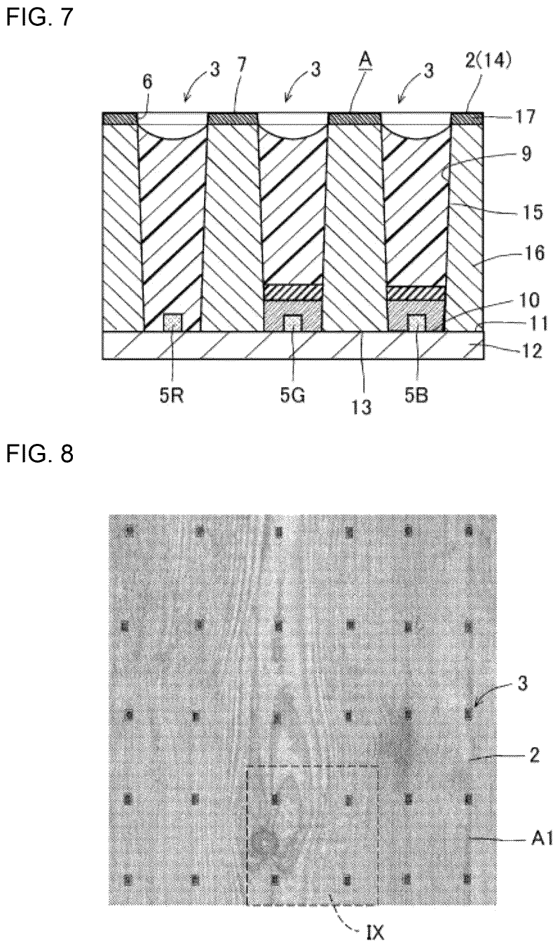

FIG. 6 is a schematic exploded partial cross-sectional view of the display device 1. FIG. 7 is a cross-sectional view of the cavity structure 4 mounted on the first substrate 12. The first substrate 12 includes the first surface 11 receiving the light emitters 5. The second substrate 16 includes the multiple through-holes 9. The multiple through-holes 9 expose multiple portions (hereafter also referred to as element-mounting portions) in the second surface 13. The element-mounting portions are also the bottom surfaces 10a of the cavities 3. Each through-hole 9 may have a section parallel to the third surface 14 being, for example, square, rectangular, circular, or in any other shape. Each through-hole 9 includes the opening 6 in the third surface 14 that may have an outer edge surrounding the outer edge of the corresponding element-mounting portion as viewed in plan. Each through-hole 9 may have a section parallel to the second surface 13 being gradually larger from the second surface 13 toward the third surface 14. This structure facilitates output of light emitted from the light emitters 5 from the display device 1. The through-holes 9 may be formed by, for example, punching, electroforming (plating), cutting, or laser beam machining. For the second substrate 16 made of a metal material or an alloy material, the through-holes 9 may be formed by, for example, punching or electroforming. For the second substrate 16 made of a semiconductor material, the through-holes 9 may be formed by, for example, photolithography including dry etching.

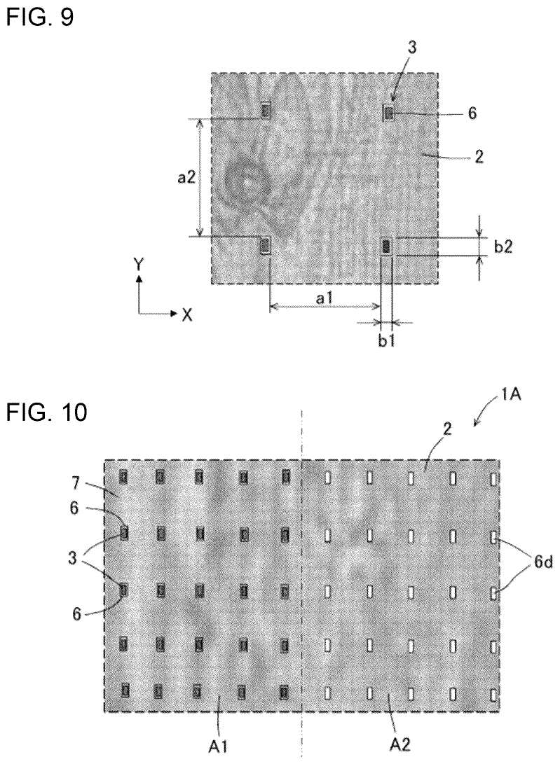

FIG. 8 is an enlarged partial plan view of the display surface 2. FIG. 9 is an enlarged partial plan view of part IX in FIG. 8. The openings 6 of the cavities 3 have a width b1 of, for example, about 10 to 300 μm in a first direction X parallel to a direction of a scanning line. The openings 6 have a width b2 of, for example, about 10 to 500 μm in a second direction Y parallel to a direction of a signal line perpendicular to the first direction X. The openings 6 are spaced in the first direction X at intervals a1 of, for example, about 50 to 2000 μm. The openings 6 are spaced in the second direction Y at intervals a2 of, for example, about 50 to 2000 μm.

The openings 6 may have a maximum width of less than or equal to 85 μm as viewed in plan. Human eyes can perceive a pixel density to a limited degree, and can perceive a point with a resolving power of about 300 pixels per inch (ppi). A pixel in a 300 ppi image corresponds to a pixel with a maximum dimension of about 85 μm. When the openings 6 have a maximum width less than or equal to 85 μm as viewed in plan, the openings 6 are less likely to be viewed as a point by a person. With the openings 6 being unviewable by a human and no light being emitted, the first area A1 and the second area A2 are viewed as continuous areas. The display device 1 thus has higher image quality. The openings 6 may have a maximum width in a range of 10 to 85 μm or 50 to 85 μm, or in any other range.

The openings 6 in the shape of a polygon such as a rectangle may have a maximum width being the length of its maximum side or maximum diagonal. The openings 6 in the shape of a circle may have a maximum width being its diameter. The openings 6 in the shape having major and minor axes such as an oval may have a maximum width being the major axis.

One opening 6 may be apart from another opening 6 adjacent to the one opening 6 at an interval greater than or equal to 85 μm. When the interval is less than 85 μm, an area between one opening 6 and an adjacent opening 6 is less likely to be viewed as an independent area. These adjacent openings 6 are more likely to be viewed continuously. This issue can be responded by the structure described above. The interval may be about 85 to 200 μm or about 85 to 500 μm, but is not limited to these ranges.

FIG. 5A is a graph showing the detailed brightness of the first area A1 and the second area A2 in portions P1, P2, and P3 in the boundary part P. FIG. 5B is an enlarged partial plan view of the part P in FIG. 5A. The left graph in FIG. 5A shows the brightness of the portion 7 of the first area A1 other than the openings 6, with the relative intensity of light separated into red light (R), green light (G), and blue light (B). The middle graph is the same or similar graph for the openings 6. The right graph is the same or similar graph for the second area A2. As in FIGS. 5A and 5B, the portions of the openings 6 are darker than, for example, the portion 7 other than the openings 6 when no light is emitted. The brightness may be adjusted to cause the portion 7 other than the openings 6 to be brighter than the second area A2 using, for example, a printed layer 17 described below. The portions of the openings 6 may be brighter than the portion 7 other than the openings 6 due to the effects from, for example, reflective layers located on the inner peripheral surfaces 15 of the cavities 3 when no light is emitted. In this case, the brightness may be adjusted to cause the portion 7 other than the openings 6 to be darker than the second area A2 using, for example, the printed layer 17 described below. This structure reduces the difference in brightness between the first area A1 including the openings 6 and the second area A2 as in FIG. 4B illustrating the display surface 2 viewed entirely, and thus reduces visual discomfort.

The first area A1 may be surrounded by the second area A2. This structure allows information to be partially displayed on a substantially middle portion (the first area A1) in an area that is not typically visible as a display portion (the first area A1 and the second area A2). The information displayed in such a manner may impress a viewer with a surprise, and may increase, for example, visual, advertisement, and promotion effects.

FIG. 10 is an enlarged partial plan view of a display device 1A according to another embodiment of the present disclosure, illustrating a boundary part P on a display surface 2. The same reference numerals denote the components corresponding to those in the above embodiments. As illustrated in FIG. 10, the display device 1A includes optical adjusters that may each be a dummy opening 6d of the through-hole 9 defining a dummy cavity. The cavity structure 4 may include a light controller located opposite to the display surface 2. More specifically, the display device 1A may include the second substrate 16 with the display surface 2 including the second area A2 with the dummy through-holes 9. The dummy through-holes 9 are the same or similar to those in the first area A1 and are formed in the same pattern. The display device 1A further includes, for example, a backlight device as a light controller behind the second substrate 16 (opposite to the display surface 2). The backlight device may include dummy cavities receiving light emitters 5 in the same or similar manner to, for example, the first substrate 12. In some embodiments, the backlight device may include hollow dummy through-holes 9 defining the dummy cavities. The backlight device may be located opposite to the display surface 2 in the first substrate 12. The backlight device may illuminate, with light emitted from a light source including, for example, multiple LEDs, the back of the first substrate 12 or the second substrate 16 through a transparent light guide. The backlight device sets the intensity of light emitted toward the back of the first substrate 12 or the second substrate 16 to reduce the difference in brightness between the first area A and the second area A2. The light controller is, for example, a light source of monochromatic light such as white light, and may control the light emission intensity. The light controller may be a light source that can adjust at least two of the brightness V, the hue H, or the chroma C that can adjust full color gradations.

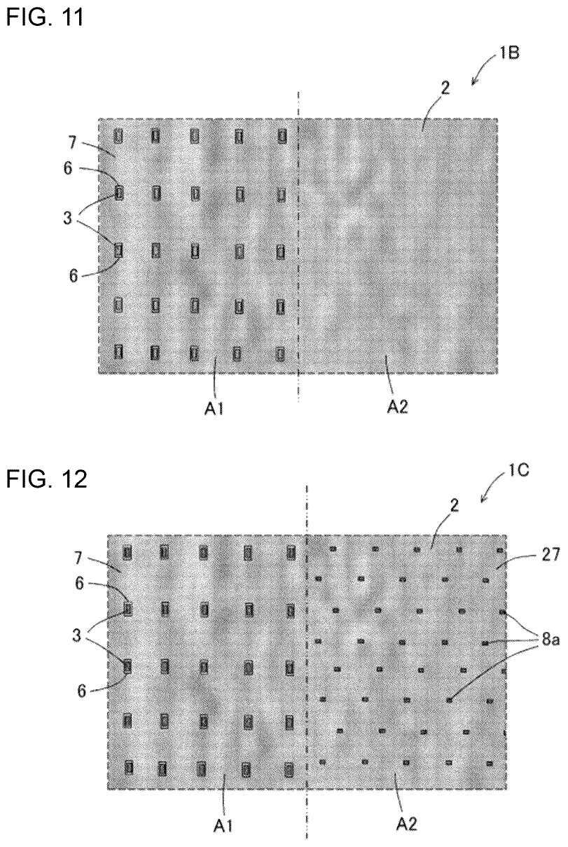

FIG. 11 is an enlarged partial plan view of a display device 1B according to another embodiment of the present disclosure, illustrating the boundary part P on the display surface 2. The display device 1B according to the present embodiment causes the light emitters 5 to emit light to allow the first area A1 displaying no information in, for example, the sleep mode to have the same brightness as and a similar color to the second area A2. In this structure, the ratio of the third brightness V3 of the first area A1 in the display state to the second brightness V2 of the second area may be in a predetermined range including 1. More specifically,

V3=V13×S11/S1+V12×S12/S1,

where V13 is the brightness of the openings 6 of the multiple cavities 3 in the display state (when the light emitters 5 are on). The ratio V3/V2 may satisfy 0.8≤V3/V2≤1.2. Further, the brightness V12 of the portion 7 may be the same as the brightness V2 of the second area A2 (V12=V2). In this case, the third brightness V3 and the second brightness V2 can be easily approximated.

The ratio of the third hue H3 of the first area A1 in the display state to the second hue H2 of the second area may be in a predetermined range including 1. More specifically,

H3=H13×S11/S1+H12×S12/S1,

where H13 is the hue of the openings 6 of the multiple cavities 3 in the display state. The ratio H3/H2 may satisfy 0.8≤H3/H2≤1.2. Further, the hue H12 of the portion 7 may be the same as the hue H2 of the second area A2 (H12=H2). In this case, the third hue H3 and the second hue H2 can be easily approximated.

The ratio of the third chroma C3 of the first area A1 in the display state to the second chroma C2 of the second area may be in a predetermined range including 1. More specifically,

C3=C13×S11/S1+C12×S12/S1,

where C13 is the chroma of the openings 6 of the multiple cavities 3 in the display state. The ratio C3/C2 may satisfy 0.8≤C3/C2≤1.2. Further, the chroma C12 of the portion 7 may be the same as the chroma C2 of the second area A2 (C12=C2). In this case, the third chroma C3 and the second chroma C2 can be easily approximated.

The structure described above allows accurate control of at least the brightness V of the brightness V, the hue H, and the chroma C of light emitted from the light emitters 5 emitting light. This yields high visual similarity between the first area A1 and the second area A2, and can further reduce discomfort for a viewer.

FIG. 12 is an enlarged partial plan view of a display device 1C according to another embodiment of the present disclosure, illustrating the boundary part P on the display surface 2. The display device 1C according to the present embodiment includes multiple colored portion 8a as the optical adjusters in the second area A2. The colored portions 8a may be printed portions formed and placed on the second area A2 with, for example, a printing method. The colored portions 8a may be adjusted to have substantially the same brightness V as the openings 6 in the non-display state. In other words, the ratio of the first brightness V1 of the first area A1 in the non-display state to the second brightness V2 of the second area may be in a predetermined range including 1. More specifically,

V1=V11×S11/S1+V12×S12/S1, and

V2=V21×S21/S1+V22×S22/S1,

where S2 is the area size of the second area A2 (where S2=S1), V21 is the brightness of the colored portions 8a, S21 is the total area size of the colored portions 8a, V22 is the brightness of a portion 27 of the second area A2 other than the colored portions 8a, and S22 is the area size of the portion 27. The ratio V1/V2 may satisfy 0.8≤V1/V2≤1.2. Further, the brightness V12 of the portion 7 may be the same as the brightness V22 of the portion 27 (V12=V22). In this case, the first brightness V1 and the second brightness V2 can be easily approximated. As illustrated in FIG. 12, a single colored portion 8a may have a smaller area size than a single opening 6, and the brightness V21 of the colored portions 8a may be darker than the brightness V11 of the openings 6. This structure allows the colored portions 8a having smaller areas to be formed at low cost.

In the structure in FIG. 12, the ratio of the first hue H1 of the first area A1 in the non-display state to the second hue H2 of the second area may be in a predetermined range including 1. More specifically,

H1=H11×S11/S1+H12×S12/S1, and

H2=H21×S21/S1+H22×S22/S1,

where H21 is the hue of the colored portions 8a, and H22 is the hue of the portion 27. The ratio H1/H2 may satisfy 0.8≤H1/H2≤1.2. Further, the hue H12 of the portion 7 may be the same as the hue H22 of the portion 27 (H12=H22). In this case, the first hue H1 and the second hue H2 can be easily approximated.

In the structure in FIG. 12, the ratio of the first chroma C1 of the first area A1 in the non-display state to the second chroma C2 of the second area may be in a predetermined range including 1. More specifically,

C1=C11×S11/S1+C12×S12/S1, and

C2=C21×S21/S1+C22×S22/S1,

where C21 is the chroma of the colored portions 8a, and C22 is the chroma of the portion 27. The ratio C1/C2 may satisfy 0.8≤C1/C2≤1.2. Further, the chroma C12 of the portion 7 may be the same as the chroma C22 of the portion 27 (C12=C22). In this case, the first chroma C1 and the second chroma C2 can be easily approximated.

In these structures with the first area A1 in the non-display mode, the colored portions 8a allow accurate control of at least the brightness V of the brightness V, the hue H, and the chroma C of the second area A2. This yields high visual similarity between the first area A1 and the second area A2, and can further reduce discomfort for a viewer.

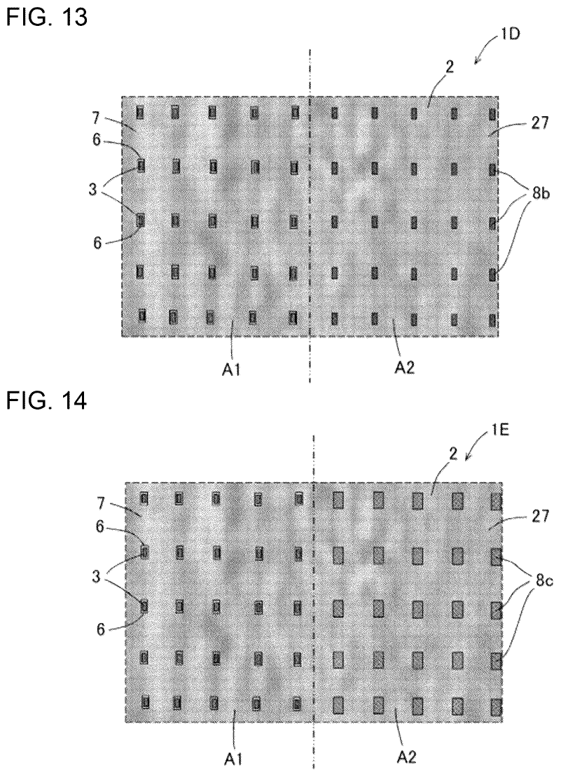

FIG. 13 is an enlarged partial plan view of a display device 1D according to another embodiment of the present disclosure, illustrating the boundary part P on the display surface 2. The display device 1D according to the present embodiment includes the second area A2 including multiple colored portions 8b. The multiple colored portions 8b have the same shape as the openings 6 of the cavity 3. Thus, when the colored portions 8b are compared with the colored portions 8a in FIG. 12, at least the brightness V of the colored portions 8b may be a bright value approximate to the value of the portion 27 and close to the value of the openings 6. The embodiment may be the same as or similar to any embodiments with the structure in FIG. 12. In other words, the colored portions 8b may be adjusted to satisfy

0.8≤V1/V2≤1.2,

0.8≤H1/H2≤1.2, and

0.8≤C1/C2≤1.2.

This structure allows the colored portions 8b to accurately control at least the brightness V of the brightness V, the hue H, and the chroma C of the second area A2 when the first area A1 is in the non-display state. This yields high visual similarity between the first area A1 and the second area A2, and can further reduce discomfort for a viewer.

FIG. 14 is an enlarged partial plan view of a display device 1E according to another embodiment of the present disclosure, illustrating the boundary part P on the display surface 2. The display device 1E according to the present embodiment includes the second area A2 including multiple colored portions 8c. The multiple colored portions 8c are larger than the openings 6 of the cavities 3. Thus, when the colored portions 8c are compared with the colored portions 8b in FIG. 13, at least the brightness V of colored portions 8c may be a bright value further approximate to the value of the portion 27 and may be brighter than the value of the openings 6. The embodiment may be the same as or similar to any embodiments with the structure in FIG. 12. In other words, the colored portions 8c may be adjusted to satisfy

0.8≤V1/V2≤1.2,

0.8≤H1/H2≤1.2, and

0.8≤C1/C2≤1.2.

This structure allows the colored portions 8c to accurately control at least the brightness V of the brightness V, the hue H, and the chroma C of the second area A2 when the first area A1 is in the non-display state. This yields high visual similarity between the first area A1 and the second area A2, and can further reduce discomfort for a viewer.

In one or more embodiments of the present disclosure, the display device may include the display surface 2 being a design surface. In this case, information can be displayed on a portion that is not typically used as a display portion. Examples of such portions include the back of a seat in a vehicle, an inner wall (e.g., a dashboard surface in an automobile) and an outer wall of a vehicle, an inner wall and an outer wall of a building, a surface of digital signage for advertisement, a surface of a home appliance, and surfaces of daily articles. The information can be instantaneously switched between being displayed and being hidden. The information displayed in such a manner may impress a viewer with a surprise, and may increase, for example, advertisement effects.

The design surface may include at least one of the group consisting of a monochromatic part, a patterned part, a text part, a natural object design part, and an artifact design part. With the design surface including a monochromatic part, examples of the display surface 2 may include the back of a seat in a vehicle, an inner wall and an outer wall of a vehicle, and surfaces of home appliances such as a surface of a washing machine, a surface of a refrigerator, and a surface of a vacuum cleaner. The monochromatic part may have any colors such as white, black, blue, and red. The design surface may include multiple monochromatic parts.

With the design surface including a patterned part, examples of the display surface 2 may include surfaces of home appliances such as a surface of a washing machine, a surface of a refrigerator, and a surface of a vacuum cleaner, and surfaces of daily articles such as surfaces of tableware and surfaces of clothing. The patterned part may be an arrangement of various geometric patterns such as a triangle, a rectangle, a polygon, a circle, a star shape, and a petal shape, or an arrangement of at least one of illustrations of, for example, fruit, animals, and vehicles, or a pattern like abstract paintings.

With the design surface including a text part, examples of the display surface 2 may include the back of a seat in a vehicle, an inner wall and an outer wall of a vehicle, an inner wall and an outer wall of a building, a surface of a digital signage display for advertisement, and a surface of a home appliance. In this case, a portion on which no information is typically displayed can newly display text such as text for advertisement and text for warning.

When the design surface including a natural object design part, examples of the natural object design part may include a wood grain pattern design part, a stone pattern design part such as a marble design, a living creature design part, a plant design part, a sky pattern design part, a sea surface design part, and a scenery design part. In this case, a portion on which no information is typically displayed can newly display a natural object design. A wood grain pattern design part is, for example, a portion on which a wood grain pattern is designed, or in other words, a portion with a freely designed wood grain pattern, and is not limited to a definite form of expression.

When the design surface includes an artifact design part, examples of the artifact design may include an instrument design part for, for example, automobiles, an animated character design part, a vehicle design part, and a design part of a daily article. In this case, a portion on which no information is typically displayed can newly display an artifact design. An animated character design part, for example, is a portion on which an animated character is designed, or in other words, a portion with a freely designed animated character, and is not limited to a definite form of expression.

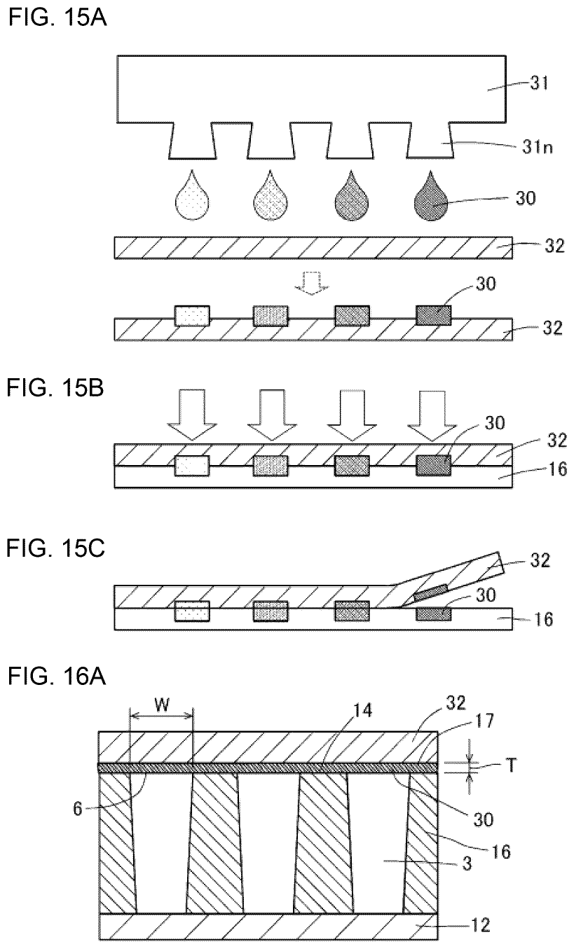

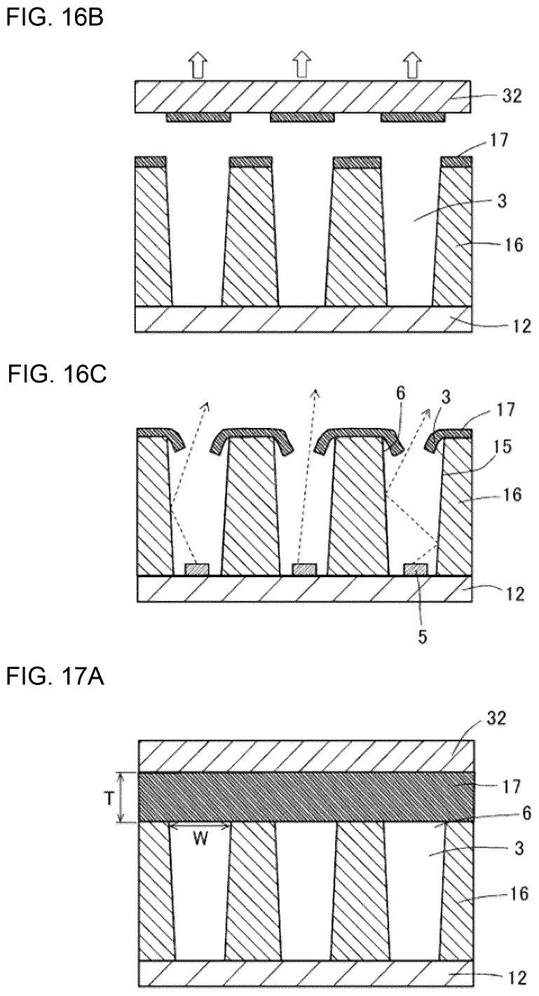

In one or more embodiments of the present disclosure, the display device may include the cavity structure 4 including a layered portion defining the display surface 2. The layered portion may have a thickness T less than half a width W of the openings 6. The structure will now be described. FIGS. 15A to 15C are diagrams of processes describing a method for forming the printed layer 17 as the layered portion on the cavities 3. FIG. 15A is a diagram illustrating a process of printing ink 30 in reverse on transfer paper 32. FIG. 15B is a diagram illustrating a process of pressing the transfer paper 32 and the second substrate 16 together with heat. FIG. 15C is a diagram illustrating a process of the ink 30 being transferred to and printed on the display surface 2 of the second substrate 16. A layer of the ink 30 fixed on the second substrate 16 is the printed layer 17 (illustrated in FIG. 16B) as the layered portion being a surface layer of the display surface 2.

First, as illustrated in FIG. 15A, the ink 30 is sprayed from an inkjet device 31

through its nozzles 31n to print the ink 30 on the transfer paper 32. The ink 30 may correspond to each cavity 3 and may be ink of different colors such as red ink, green ink, and blue ink. As illustrated in FIG. 15B, the transfer paper 32 and the second substrate 16 being a transfer subject are pressed together with heat. As illustrated in FIG. 15C, the transfer paper 32 is finally peeled off from the second substrate 16. At the same time, a pattern of the ink 30 covering the cavities 3 is printed on the display surface 2 (the third surface 14) of the second substrate 16, and is fixed on the display surface 2 when liquid components of the ink 30, such as solvent components and resin components, are evaporated. The dry transfer method may transfer a layer of the ink 30 onto the third surface 14 of the second substrate 16 to form the printed layer 17.

FIGS. 16A to 16C are diagrams describing a procedure for forming the printed layer 17 on the second substrate 16. FIG. 16A is a partial cross-sectional view of the second substrate 16 with the transfer paper 32 attached on the substrate. FIG. 16B is a partial cross-sectional view of the second substrate 16 after the transfer paper 32 is peeled off and a layer of the ink 30 is transferred. FIG. 16C is a partial cross-sectional view of the second substrate 16 with the layer of the ink 30 (the printed layer 17) transferred. In the present embodiment, the thickness T of the printed layer 17 is less than half the width W of the openings 6 (T<W/2). As illustrated in FIG. 16C, when the transfer paper 32 is peeled off from the second substrate 16, the printed layer 17 is disconnected in the portions of the openings 6 and is less likely to close the openings 6. Before drying, the viscous printed layer 17 may drip from the third surface 14 toward the inner peripheral surfaces 15 of the cavities 3 through the openings 6. In this case, the amount of the printed layer 17 entering the inner peripheral surfaces 15 of the cavities 3 is smaller. The printed layer 17 thus does not prevent light emitted from the light emitters 5 from exiting the cavities 3. For the openings 6 in the shape of, for example, an oval, the openings 6 have a minimum width and its width W is the minimum width. For the openings 6 in the shape of, for example, a circle, the openings 6 has a uniform width and its width W is the width. Thus, the width W of the openings 6 may include a minimum width.

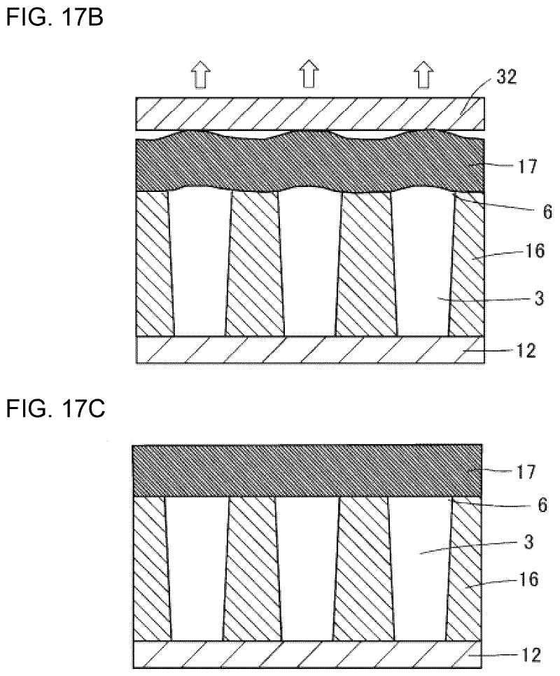

As illustrated in FIGS. 17A to 17C, when the thickness T of the printed layer 17 is greater than or equal to half the width W of the openings 6, the entire layer of the ink 30 on the transfer paper 32 is transferred to the second substrate 16. The transferred printed layer 17 is likely to close the openings 6. With the layer of the ink 30 closing the openings 6, light emitted from the light emitters 5 cannot exit the cavities 3. Thus, the printed layer 17 may have the thickness T less than half the width W of the openings 6.

In another embodiment of the present disclosure, the printed layer 17 may be

formed with, in place of the dry transfer method described above that uses the transfer paper 32, the roller coating method that uses a transfer roller to coat the second substrate 16 with ink. The layered portion may not be formed with a printing method, and may be formed with, for example, a coating method.

In one or more embodiments of the present disclosure, the display device includes

the first area for displaying information with light from the light emitters and the second area including no light emitter. The first area and the second area are likely to be viewed as continuous areas when the light emitters emit no light. The first area, which emits light for display, is thus less likely to be unintendedly viewed intermittently with respect to the second area when no light is emitted. This reduces discomfort for a viewer and allows the display device to have higher image quality when no light is emitted.

Although the embodiments of the present disclosure have been described in detail, the present disclosure is not limited to the embodiments described above, and may be changed or varied in various manners without departing from the spirit and scope of the present disclosure. The components described in the above embodiments may be entirely or partially combined as appropriate unless any contradiction arises.

### REFERENCE SIGNS

1, 1A, 1B, 1C, 1D, 1E display device
2 display surface
3 cavity
4 cavity structure
5, 5R, 5G, 5B light emitter
6 opening of cavity 3
7 portion of first area A1 other than openings 6
8a, 8b, 8c colored portion in second area A2
9 through-hole
10 first surface
10a bottom surface of cavity 3
11 first surface
12 first substrate
13 second surface
14 third surface
15 inner peripheral surface of cavity 3
16 second substrate
17 printed layer
27 portion of second area A2 other than colored portions 8a, 8b, and 8c
A1 first area
A2 second area

1. A display device, comprising:
a cavity structure including a display surface and a cavity in the display surface; and
a light emitter in the cavity,
wherein the display surface includes a first area configured to display information with light emitted from the light emitter in the cavity and a second area adjacent to the first area, and
a ratio of a first brightness of the first area in a non-display state to a second brightness of the second area is in a predetermined range including 1.

2. The display device according to claim 1, wherein
V1=V11×S11/S1+V12×S12/S1, and S1=S11+S12, where S1 is an area size of the first area, V11 is a brightness, defined by a Munsell color system, of an opening of the cavity in the first area in the non-display state, S11 is a total area size of the opening in the first area, V12 is a brightness of a portion of the first area other than the opening, S12 is an area size of the portion of the first area other than the opening, V1 is the first brightness, and V2 is the second brightness, and
the predetermined range is 0.8≤V1/V2≤1.2.

3. The display device according to claim 2, wherein
the opening in the non-display state has the brightness V11 lower than the brightness V12 of the portion of the first area other than the opening.

4. The display device according to claim 1, wherein
a ratio of a first hue of the first area in the non-display state to a second hue of the second area is in a predetermined range including 1.

5. The display device according to claim 4, wherein
H1=H11×S11/S1+H12×S12/S1, and S1=S11+S12, where S1 is an area size of the first area, H11 is a hue, defined by a Munsell color system, of an opening of the cavity in the first area in the non-display state, S11 is a total area size of the opening in the first area, H12 is a hue of a portion of the first area other than the opening, S12 is an area size of the portion of the first area other than the opening, H1 is the first hue, and H2 is the second hue, and
the predetermined range is 0.8≤H1/H2≤1.2.

6. The display device according to claim 1, wherein
a ratio of a first chroma of the first area in the non-display state to a second chroma of the second area is in a predetermined range including 1.

7. The display device according to claim 6, wherein
C1=C11×S11/S1+C12×S12/S1, and S1=S11+S12, where S1 is an area size of the first area, C11 is a chroma, defined by a Munsell color system, of an opening of the cavity in the first area in the non-display state, S11 is a total area size of the opening in the first area, C12 is a chroma of a portion of the first area other than the opening, S12 is an area size of the portion of the first area other than the opening, C1 is the first chroma, and C2 is the second chroma, and
the predetermined range is 0.8≤C1/C2≤1.2.

8. The display device according to claim 1, wherein
the second area includes an optical adjuster corresponding to an opening of the cavity, and the optical adjuster adjusts the second brightness.

9. The display device according to claim 8, wherein
a ratio of a brightness of the opening of the cavity in the non-display state to a brightness of the optical adjuster is in a predetermined range including 1.

10. The display device according to claim 9, wherein
0.9≤V11/V21≤1.1, where V11 is the brightness, defined by the Munsell color system, of the opening of the cavity in the non-display state, and V21 is the brightness of the optical adjuster.

11. The display device according to claim 8, wherein
the optical adjuster is a dummy opening of a through-hole defining a dummy cavity, and
the cavity structure includes a light controller opposite to the display surface.

12. The display device according to claim 1, wherein
the display surface is a design surface.

13. The display device according to claim 12, wherein
the design surface includes at least one of the group consisting of a monochromatic part, a patterned part, a text part, a natural object design part, and an artifact design part.

14. The display device according to claim 1, wherein
the cavity structure includes a layered portion defining the display surface, and
the layered portion has a thickness less than half a width of an opening of the cavity.

15. The display device according to claim 1, wherein
an opening of the cavity has a maximum width less than or equal to 85 μm.

16. The display device according to claim 15, wherein
the opening is apart from another opening adjacent to the opening at an interval greater than or equal to 85 μm.

17. The display device according to claim 1, wherein
the first area is surrounded by the second area.
